(19) United States
(12) Patent Application Publication
(10) Pub. No.: US 2022/0109395 A1
(43) Pub. Date: Apr. 7, 2022

(54) SYSTEM, APPARATUS, AND METHOD FOR PROVIDING A POWER SOURCE

(71) Applicant: National Christmas Products LLC, Cranford, NJ (US)

(72) Inventor: Michael M. McRae, Ormond Beach, FL (US)

(21) Appl. No.: 17/061,775

(22) Filed: Oct. 2, 2020

(51) Int. Cl. H02S 20/30; H02S 40/38; H02J 7/00; H01L 35/02

(52) U.S. Cl. CPC H02S 20/30; H02S 40/38; H02J 7/0063; A45B 25/00; H02J 2207/30; H02J 2300/24; H01L 35/02

(57) ABSTRACT

An apparatus for removably receiving a container is disclosed. The apparatus has a structural assembly having a cavity configured to removably receive the container, a renewable power source supported by the structural assembly, an electrical component including a power storage supported by the structural assembly, a thermal assembly disposed at the cavity and configured to heat or cool the container when the container is received in the cavity, and an elongated support member attached to the structural assembly and configured to be inserted into the ground.

### TECHNICAL FIELD

The present disclosure generally relates to a system, apparatus, and method for providing a power source, and more particularly to a system, apparatus, and method for providing a power source for equipment.

### BACKGROUND

Conventional outdoor recreational equipment such as beach equipment and camping equipment sometimes includes a power source for charging cell phones, LED lights, and USB-connected electronic devices. Such equipment sometimes also includes solid-state thermal cooling or heating devices to keep liquids or food cool or heated.

These conventional power sources are typically configured for independent use, with a given item of equipment including a stand-alone power source for powering that given item. Accordingly, if a given power source for a given piece of equipment is inoperable or otherwise unavailable, then that given piece of equipment will not be able to be powered using conventional power sources and equipment.

The exemplary disclosed system, apparatus, and method are directed to overcoming one or more of the shortcomings set forth above and/or other deficiencies in existing technology.

### SUMMARY OF THE DISCLOSURE

In one exemplary aspect, the present disclosure is directed to an apparatus for removably receiving a container. The apparatus includes a structural assembly having a cavity configured to removably receive the container, a renewable power source supported by the structural assembly, an electrical component including a power storage supported by the structural assembly, a thermal assembly disposed at the cavity and configured to heat or cool the container when the container is received in the cavity, and an elongated support member attached to the structural assembly and configured to be inserted into the ground.

In another exemplary aspect, the present disclosure is directed to a method. The method includes a structural assembly having a cavity configured to removably receive a container, supporting a renewable power source with the structural assembly, supporting an electrical component including a power storage and a controller with the structural assembly, heating or cooling the container when the container is received in the cavity using a thermal assembly disposed at the cavity, removably attaching an elongated support member to the structural assembly, and supporting the structural assembly on the ground by inserting the elongated support member into the ground.

### BRIEF DESCRIPTION OF THE DRAWINGS

FIG. 1 illustrates a top view of at least some exemplary embodiments of the present disclosure;

FIG. 2 illustrates a perspective view of at least some exemplary embodiments of the present disclosure;

FIG. 3 illustrates a perspective view of at least some exemplary embodiments of the present disclosure;

FIG. 4 illustrates a perspective view of at least some exemplary embodiments of the present disclosure;

FIG. 5 illustrates a perspective view of at least some exemplary embodiments of the present disclosure;

FIG. 6 illustrates a schematic view of at least some exemplary embodiments of the present disclosure;

FIG. 7 illustrates a perspective view of at least some exemplary embodiments of the present disclosure;

FIG. 8 illustrates a schematic view of at least some exemplary embodiments of the present disclosure;

FIG. 9 illustrates a perspective view of at least some exemplary embodiments of the present disclosure;

FIG. 10 illustrates a schematic view of at least some exemplary embodiments of the present disclosure;

FIG. 11 illustrates a perspective view of at least some exemplary embodiments of the present disclosure;

FIG. 12 illustrates a perspective view of at least some exemplary embodiments of the present disclosure; and

FIG. 13 illustrates a schematic view of at least some exemplary embodiments of the present disclosure.

### DETAILED DESCRIPTION AND INDUSTRIAL APPLICABILITY

The exemplary disclosed system, apparatus, and method may include equipment having a power source. In at least some exemplary embodiments, the exemplary disclosed system, apparatus, and method may include outdoor equipment such as, for example, beach and camping equipment. The exemplary disclosed power source may include one or more solar panels.

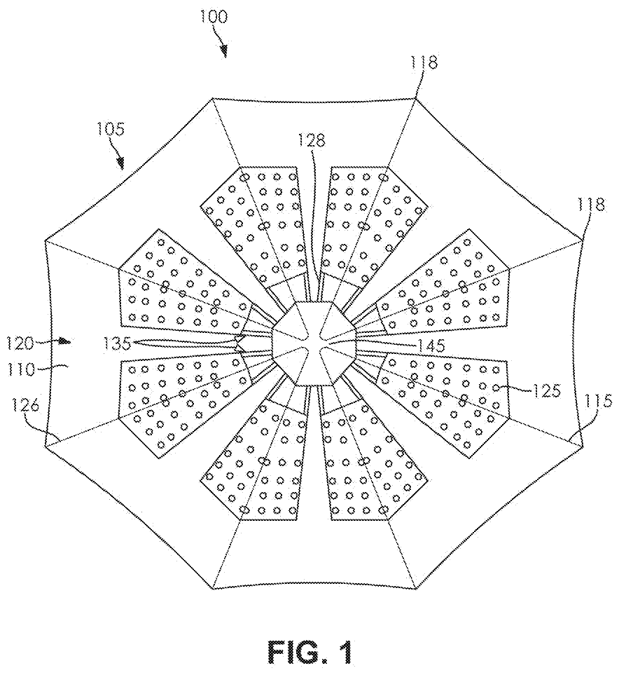

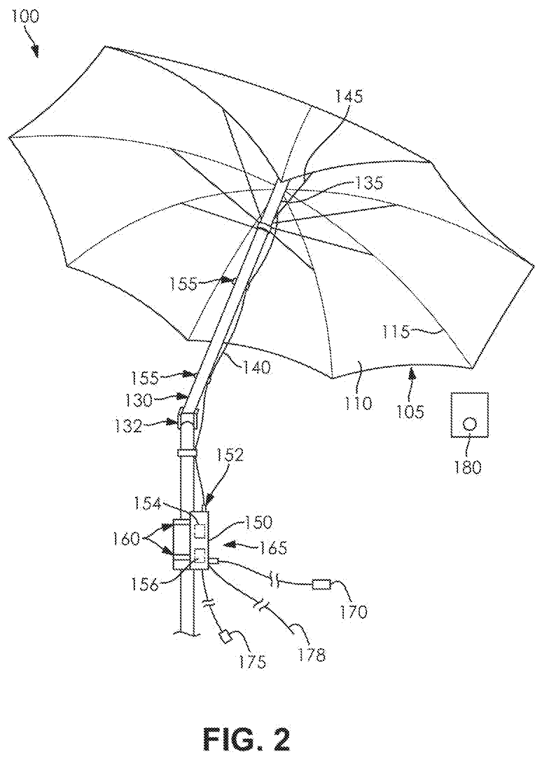

FIGS. 1 and 2 illustrate an exemplary system 100. System 100 may be any suitable type of equipment such as outdoor equipment. For example, system 100 may be beach equipment or camping equipment. In at least some exemplary embodiments, system 100 may be an umbrella system including an umbrella. System 100 may include a beach umbrella.

System 100 may include a structural assembly 105. Structural assembly 105 may be any suitable piece of equipment on which components of system 100 may be mounted. In at least some exemplary embodiments, system 100 may be an umbrella such as, for example, a beach umbrella. Structural assembly 105 may include a sheet member 110. Sheet member 110 may be for example an elongated flexible member that may extend across structural assembly 105. For example, sheet member 110 may be a thin member formed from plastic material such as nylon, polyester, or any other suitable plastic material. Sheet member 110 may be formed from any suitable fabric or textile for forming an elongated flexible member. For example, sheet member 110 may form the canopy of structural assembly 105 that may be an umbrella.

Structural assembly 105 may also include a plurality of members 115. Member 115 may be any suitable structural member for movably supporting sheet member 110. For example, member 115 may be formed from metal, plastic, wood, or any other suitable structural material. Member 115 may be a strut or rib of structural assembly 105 that may be an umbrella. Each member 115 may form a fold line of sheet member 110. Sheet member 110 may include an elastic seam at each member 115 that may be aligned with each member 115 (e.g., disposed at each fold line of member 115). Sheet member 110 may thereby be folded at each of its elastic seams aligned with respective members 115 and be folded about the fold lines formed by members 115 (e.g., when structural assembly 105 is moved between an open and a closed configuration such as between an opened and closed umbrella). A fastener 118 may be disposed at an end portion of each member 115 for example as illustrated in FIG. 1. Fastener 118 may be any suitable fastener such as, for example, a retaining ring, a clip, a hook and loop fastener, or any other suitable fastening device.

As illustrated in FIG. 1, system 100 may include a power source assembly 120. Power assembly 120 may include one or more (e.g., a plurality) of power sources 125. Power source 125 may be any suitable power source for providing power such as electrical power to system 100. Power source 125 may be a renewable power source (e.g., a solar energy, wind energy, kinetic energy, and/or any other suitable renewable power source). Power source 125 may be a solar energy source. For example, power source 125 may include one or more solar energy panels. Power source 125 may include thin-film, monocrystalline, Graphene, and/or polycrystalline solar panels. Power source 125 may include photovoltaic (PV) and/or thermal solar energy units. Power source 125 may also include wind power energy units (e.g., wind turbine), kinetic power energy units, and/or any other desired renewable or non-renewable power sources. In at least some exemplary embodiments, power source 125 may be a flexible thin film solar panel. For example, power source 125 may be a foldable panel. Power source 125 may be any suitable voltage power source such as, for example, of between about 0.5V and about 12V or more (e.g., about 3V or 6V).

Power source 125 may be attached or mounted to member 115. For example as illustrated in FIG. 1, a plurality of power sources 125 may each be attached or mounted to respective member 115. A centerline of each power source 125 may be substantially aligned along a centerline of each member 115 so that each power source 125 may be folded along a respective member 115 that forms a fold line for example as described above. Power source 125 may be attached or mounted to member 115 by any suitable technique (e.g., by any suitable fastening device such as mechanical fasteners and/or adhesive). For example, a first securing strap 126 (e.g., a flexible or elastic strap) may attach a first end portion of power source 125 to member 115 (e.g., to fastener 118). A second securing strap 128 (e.g., a flexible or elastic strap) may attach a second end portion of power source 125 to an end portion of a center member 130 (e.g., a center pole) of structural assembly 105. As illustrated in FIG. 2, center member 130 may include a joint 132. Joint 132 may be any suitable joint such as, for example, a selectively lockable rotatable joint (e.g., a tilt joint) that may allow a user to tilt an upper portion of center member 130 relative to a lower portion of center member 130.

Power sources 125 may be electrically connected. Power sources 125 may be electrically connected to each other in any suitable configuration to produce a desired voltage for planned usage of system 100. For example, power sources 125 may be electrically connected to each other in series or parallel. A plurality of electrical connectors 135 may electrically connect power sources 125. Electrical connectors 135 may be electrical cables, wires, cords, or any other suitable electrical connection. As illustrated in FIG. 2, electrical connectors 135 may be electrically connected to an electrical connector 140. Electrical connector 140 may be similar to electrical connector 135.

As illustrated in FIGS. 1 and 2, electrical connector 140 may extend through a movable portion 145, from an upper portion of structural assembly 105 to a lower portion of structural assembly 105. Movable portion 145 may be for example a flap (e.g., wind vent flap) of structural assembly 105. Electrical connector 140 may extend from electrical connectors 135 to an electrical connection 152 of an electrical component 150. Electrical connectors 135 and electrical connector 140 may thereby electrically connect power sources 125 to electrical component 150. Electrical connector 140 may be fastened to center member 130 via one or more fasteners 155. Fasteners 155 may be any suitable fastener such as, for example, a clip (e.g., cable clip), a clamp, a strap, a hook and loop fastener, and/or any other suitable fastener. Electrical component 150 may be attached or mounted to center member 130 via one or more fasteners 160 that may be similar to fastener 155. In at least some exemplary embodiments, fasteners 160 may be snap-on clamps that may attach electrical component 150 to center member 130 (e.g., electrical component 150 may extend or wrap, e.g. about one-half to three-quarters or more, around center member 130 when fasteners 160 clamp electrical component 150 to center member 130).

Electrical component 150 may include any suitable energy storage component (e.g., a power storage 156). Electrical component 150 may include a rechargeable battery (e.g., power storage 156). For example, Electrical component 150 may include a nickel-metal hydride battery, a lithium-ion battery, an ultracapacitor battery, a Graphene battery, a lead-acid battery, and/or a nickel cadmium battery. Electrical component 150 may include any suitable power storage that may be charged or recharged with electricity from power sources 125 and that may provide power to system 100.

Electrical component 150 may also include a connector assembly 165. Connector assembly 165 may include a plurality of electrical connectors 170, 175, and 178 (e.g., any desired number of electrical connectors) that may provide for power output and/or input items or devices to be connected for example as described herein. For example, any desired number of electrical connectors 170, 175, and 178 may provide electrical connectors such as USB connectors, power cables, charging cables (e.g., an external charging cable of any suitable voltage level such as, for example, 12V), electrical plugs, electrical sockets, electrical cable connectors, and/or any other suitable electrical connector for electrically connecting electrical component 150 with any suitable electrical device (e.g., to charge the devices).

Electrical component 150 may also include a controller. The controller (e.g., controller 154) may control an operation of some or all components of system 100. The controller of electrical component 150 may be any suitable computing device for controlling an operation of components of system 100. The controller may, for example, include a processor (e.g., micro-processing logic control device) or board components. Also for example, the controller may include input/output arrangements that allow it to be connected (e.g., via wireless, Wi-Fi, Bluetooth, or any other suitable communication technique) to other components of system 100. For example, the controller may control an operation of components of system 100. System 100 may include one or more modules that may be partially or substantially entirely integrated with one or more components of system 100 such as, for example, electrical component 150. For example, the one or more modules may include computer-executable code stored in non-volatile memory. The one or more modules may also operate using a processor (e.g., of the controller of electrical component 150). The one or more modules may store data and/or be used to control some or all of the exemplary disclosed processes described herein. The controller (e.g., controller 154) of electrical component 150 may communicate with any suitable components of system 100 via any suitable communication method such as, for example, wireless communication (e.g., CDMA, GSM, 3G, 4G, and/or 5G), direct communication (e.g., wire communication), Bluetooth communication coverage, Near Field Communication (e.g., NFC contactless communication), radio frequency communication (e.g., RF communication such as short-wavelength radio waves, e.g., UHF waves), and/or any other desired communication technique.

Electrical component 150 may be controlled by and/or operate with a user device 180. For example, electrical component 150 may exchange data with (e.g., receive input from or transfer output to) user device 180 via the exemplary disclosed communication techniques described above. User device 180 may be any suitable user device for use with electrical component 150 such as, for example a mobile device (e.g., a smartphone, a tablet, a smartboard, and/or any suitable computer device), a computer keyboard and monitor (e.g., desktop or laptop), an audio-based device for entering input and/or receiving output via sound, a tactile-based device for entering input and receiving output based on touch or feel, a smart watch, Bluetooth headphones, a dedicated user device or interface designed to work specifically with other components of system 100, and/or any other suitable user device or interface.

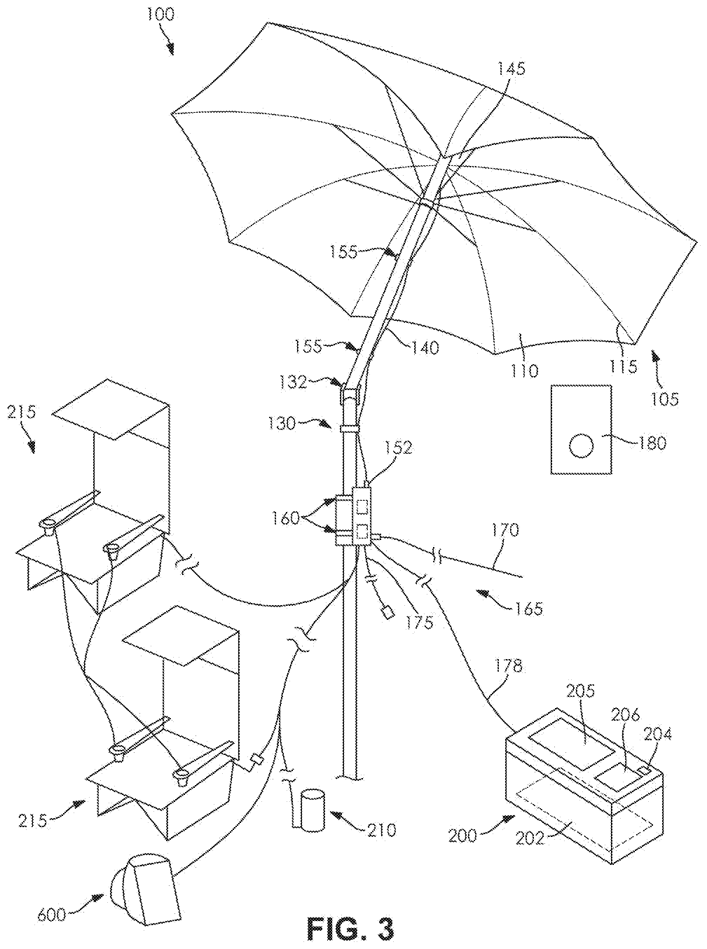

FIG. 3 illustrates an exemplary configuration and operation of system 100 with a plurality of devices. As described for example herein, the plurality of devices may include power sources and power may be transferred between system 100 (e.g., electrical component 150) and the plurality of devices.

A thermal device 200 for example similar to the devices described herein may be electrically connected to system 100 via connector assembly 165 (e.g., via electrical connector 178 that may be for example a 12V charging cable). Thermal device 200 may be a thermal cooler, a thermal backpack, or any other suitable device. In at least some exemplary embodiments, thermal device 200 may be a solar-paneled thermal food container (e.g., a cooler), backpack, and/or warmer having any suitable level of voltage (e.g., 12V or any other suitable level). Thermal device 200 may be of any suitable voltage level such as, for example, 12V or any other desired voltage. Thermal device 200 may include one or more power sources 205 that may be similar to power source 125. Thermal device 200 may also include an electrical component 206 that may be similar to electrical component 150 and that may for example include a power storage such as a battery (e.g., and/or a controller).

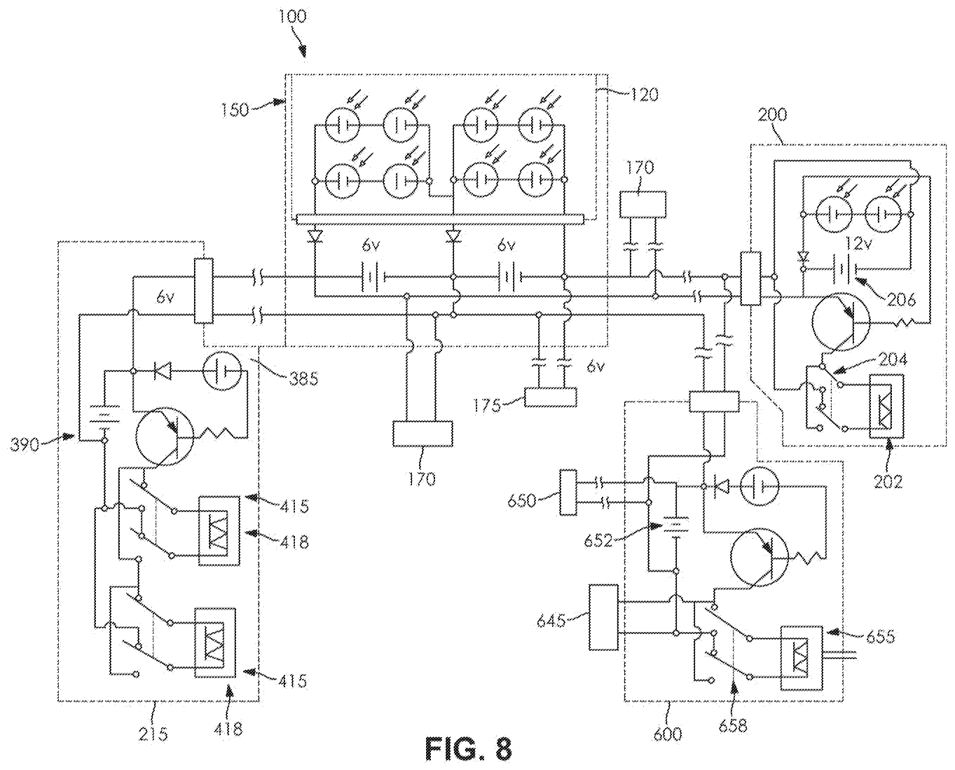

Thermal device 200 may include a thermal component 202. Thermal component 200 may be for example a heating and/or cooling panel that may include a thermal assembly similar to as described herein regarding FIG. 6. Thermal device 200 may also include an electrical switch 204. Electrical switch 204 may be any suitable electrical switch or relay for controlling an electrical circuit for example as illustrated in FIG. 8. Returning to FIG. 3, electrical switch 204 may be a reversal switch that may reverse a polarity of a circuit of thermal component 202 for example as described below regarding FIG. 6. Electrical switch 204 may thereby selectively control whether thermal device 200 operates to heat or cool and/or turns on and off.

A thermal device 210 for example as described further below may be electrically connected to system 100 via connector assembly 165 (e.g., via electrical connector 175). Thermal device 210 may be a thermal beverage holder such as a chilled or heated drink holder (e.g., an individual thermal cup holder). Thermal device 210 may include a power source similar to power source 125. Also for example, electrical connector 175 (e.g., and/or electrical connector 170 and 178) may include a USB or other suitable connector for charging a device such as cell phone, laptop, or other electronic device.

One or more systems 215 for example as described further below may be electrically connected to system 100 via connector assembly 165 (e.g., via electrical connector 175). For example as described further below, system 215 may be a chair (e.g., a foldable chair) including power sources such as solar panels and including thermal beverage holders.

One or more systems 600 for example as described further below may be electrically connected to system 100 via connector assembly 165 (e.g., via electrical connector 175). For example as described further below, system 600 may be a backpack including power sources such as solar panels and including thermal beverage heaters or coolers. In at least some exemplary embodiments, system 600 may be a solar backpack of any desired voltage level (e.g., 12V or any other suitable level).

The exemplary disclosed thermal devices for example as illustrated in FIG. 3 may heat or cool their contents (e.g., by reversing the current leads). The exemplary disclosed power sources (e.g., power sources 125 and 205 and power sources of system 215 and/or 600 and/or thermal device 210) may each produce electrical energy for use by their respective systems and/or other systems of system 100. For example, power sources 125 and 205 and power sources of system 215 and/or 600 and/or thermal device 210 may be electrically connected to electrical component 150 for example as described herein and illustrated in FIGS. 2 and 3 (e.g., via electrical connectors 135, 140, 170, 175, and/or 178). Electrical power collected or generated by power sources 125 and 205 and power sources of system 215 and/or 600 and/or thermal device 210 may thereby be transferred to electrical component 150 to charge the exemplary disclosed power storage of electrical component 150 and/or to be directed based on control by electrical component 150. For example, the exemplary disclosed controller of electrical component 150 may control a flow of electricity (e.g., of electrical power) through system 100. For example, the exemplary disclosed controller of electrical component 150 may operate to receive, store, and/or direct a flow of electrical power via electrical component 150. Electrical component 150 may thereby for example, transfer electrical power collected or generated by power sources 125 and 205 and power sources of system 215 and/or 600 and/or thermal device 210 to or from any of thermal devices 200 and 210 and/or systems 215 and/or 600 to power thermal devices 200 and 210 and/or systems 215 and/or 600. Also for example, thermal device 200, thermal device 210, and/or system 215 may include an electrical component that may be similar to electrical component 150 and that may operate, store energy, and/or control electrical current of system 100 similarly to electrical component 150.

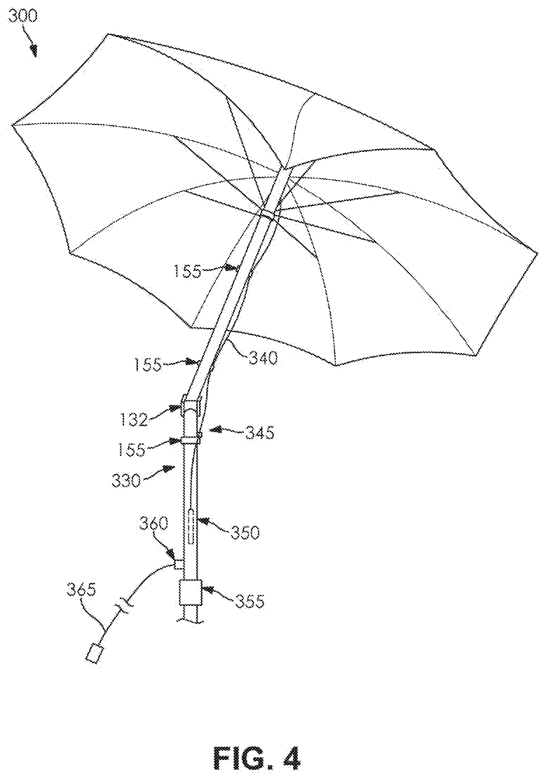

FIG. 4 illustrates another exemplary embodiment of the exemplary disclosed system, apparatus, and method. As illustrated in FIG. 4, system 300 may be generally similar to system 100. System 300 may include an electrical connector 340 that may be similar to electrical connector 140. Electrical connector 340 may be electrically connected to electrical components disposed inside of a center member 330, which may be similar to center member 130, via electrical connection to a connection 345 of an electrical component 350. For example, electrical connection 345 may be electrically connected to electrical component 350 and may extend through a wall portion of center member 330. Electrical component 350 may be similar to electrical component 150. Electrical component 350 may be disposed inside of a cavity of center member 330 (e.g., center member 330 may be a hollow member such as a hollow tube or pole or other suitable hollow shape). A user may access electrical component 350 via a movable assembly 355. For example, movable assembly 355 may include a threaded assembly such as a screw collar or any other suitable mechanical assembly that may be manipulated by a user to selectively access electrical component 350. In at least some exemplary embodiments, movable assembly 355 may allow a user to detach (e.g., unscrew) sections (e.g., pole sections) of center member 330 to access a cavity of center member 330 in which electrical component 350 may be disposed. System 300 may also include one or more electrical connectors 365, which may be similar to electrical connectors 170, 175, and 178, and may be connected to a connection 360 of electrical component 350. Connection 360 may be similar to connection 345.

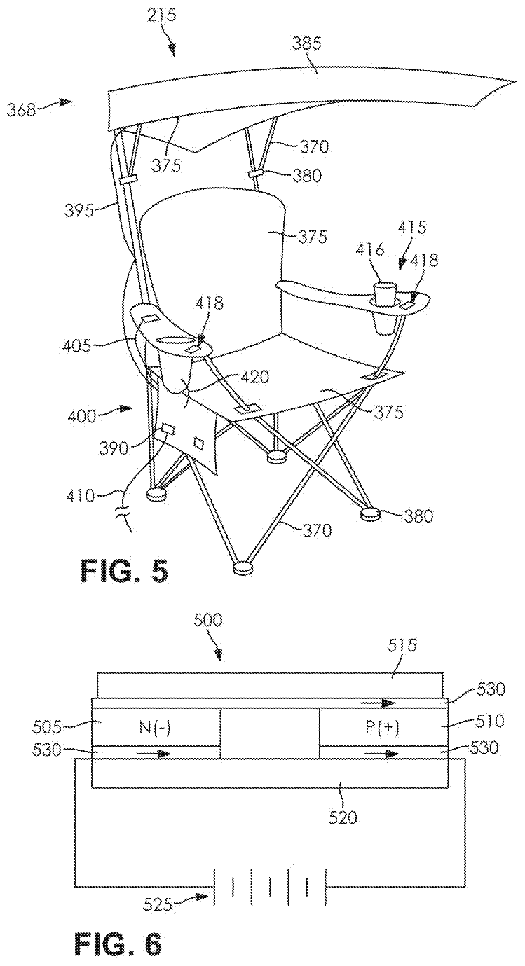

FIG. 5 illustrates system 215, an exemplary embodiment of a system that may be electrically connected to system 100 as described above. System 215 may include a structural assembly 368. Structural assembly 368 may include a plurality of members 370 and sheet members 375 that may be configured (e.g., fixedly and/or movably attached together) to form any desired piece of equipment such as, for example, a piece of furniture such as a chair (e.g., a collapsible chair) or a table or any other desired equipment. For example, members 370 may be movably attached (e.g., rotatably attached) via joints 380 (e.g., any suitable mechanical joint). Member 370 may be formed from similar material as member 115, and sheet member 375 may be formed from similar material as sheet member 110. In at least some exemplary embodiments, system 215 may be a collapsible chair for example for use in camping, the beach (e.g., a beach chair), or other outdoor or indoor activities.

System 215 may also include a power source 385 that may be similar to power source 125. In at least some exemplary embodiments, power source 385 may be a flexible think film solar panel of any suitable voltage (e.g., 6V). Power source 385 may be disposed at an upper portion of structural assembly 368 such as, for example, at one or more sheet members 375 and members 370 forming a canopy (e.g., a sun shade) of structural assembly 368. Power source 385 may be attached to structural assembly 368 similarly to the attachment of power source 125 to structural assembly 105.

System 215 may include an electrical component 390 that may be similar to electrical component 150. For example, electrical component 390 may include a power storage and a controller similar to electrical component 150. Electrical component 390 may be disposed at any desired location of structural assembly 368 such as, for example, under an armrest of seat when structural assembly 368 may form a chair. An electrical connector 395 that may be similar to electrical connector 140 may electrically connect power source 385 and electrical component 390. Electrical component 390 may include a connector assembly 400 that may be similar to connector assembly 165. For example, connector assembly 400 may include one or more electrical connectors 405 and 410 that may be similar to electrical connectors 170, 175, and 178. In at least some exemplary embodiments, electrical connector 405 may be a USB charging connector or any other desired electrical connector for example as described herein. In at least some exemplary embodiments, electrical connector 410 may be an electrical cable that may be connected to electrical component 150. For example, electrical connector 410 may electrically connect electrical component 390 and electrical component 150 so that electrical components 390 and/or 150 may control electrical flow and/or charging (e.g., power flow) to and from the exemplary disclosed devices of system 100.

System 215 may include one or more thermal devices 415. Thermal device 415 may include a cup holder assembly that may removably receive a container 416 such as a beverage or food container (e.g., a hot or cold beverage or food container such as a can, bottle, or other receptacle). Thermal device 415 may include a heating and/or cooling component that may be similar to the components of the exemplary thermal devices described herein (e.g., regarding FIG. 6). In at least some exemplary embodiments, thermal device 415 may be a heating and/or cooling thermal metallic cup holder. Thermal device 415 may be electrically connected to electrical component 390 and/or power source 385 via an electrical connector 420 that may be similar to electrical connector 140. Electrical component 390 and/or power source 385 may thereby power an operation of one or more thermal devices 415 via one or more electrical connectors 420. Thermal device 415 may include an electrical switch 418 that may be similar to electrical switch 204. Electrical switch 418 may reverse a polarity of a circuit of a thermal component of thermal device 415 for example as described below regarding FIG. 6. Electrical switch 418 may thereby selectively control whether thermal device 415 operates to heat or cool and/or turns on and off.

FIG. 6 illustrates a thermal assembly 500 that may be included in (e.g., integrated into) any of the exemplary thermal devices described herein regarding FIGS. 1-5 and 7-13 such as, for example the exemplary disclosed beverage or food holders, coolers, heaters, backpacks, sleeping bags, tents, and/or any other suitable device. In at least some exemplary embodiments, thermal assembly 500 may be a “Seebeck” effect solid state mechanism that may use DC current to transfer heat between two surfaces. Thermal assembly 500 may include a first semiconductor 505, a second semiconductor 510, a first side portion 515, a second side portion 520, and an electrical source 525. Electrical source 525 may be similar to any of the exemplary power sources and electrical components described herein such as electrical component 150 and power source 125 (e.g., these exemplary components may serve as electrical source 525 in the exemplary disclosed configurations). Electrical source 525 may also be an energy storage such as a battery having any desired voltage (e.g., 6V or any other desired level). First semiconductor 505 may be a N (−) negative “doped” semiconductor and second semiconductor 510 may be a P (+) positive “doped” semiconductor. Semiconductors 505 and 510 may be in contact with first side portion 515 and second side portion 520 that may be thermal surfaces. Thermal assembly 500 may include one or more transfer members 530. Transfer member 530 may be any suitable thin film member. For example, transfer member 530 may be any suitable thermal conductor. In at least some exemplary embodiments, transfer member 530 (e.g., and/or side portions 515 and 520) may be formed from Graphene material. For example, transfer member 530 (e.g., and/or side portions 515 and 520) may be Graphene sheets. The exemplary disclosed transfer members may be disposed above heat transfer metallic surfaces of thermal assembly 500. Transfer members 530 (e.g., and/or side portions 515 and 520) may serve to transfer heat to and from semiconductors 505 and 510. Reversing a polarity of thermal assembly (e.g., based on an operation of electrical source 525 and the exemplary disclosed electrical switch) may reverse heating and cooling sides of thermal assembly 500. For example, either of first side portion 515 and second side portion 520 may be the heating side or the cooling side based on the polarity (e.g., side portion 515 may be the heating side and side portion 520 may be the cooling side, or side portion 515 may be the cooling side and side portion 520 may be the heating side based on the polarity).

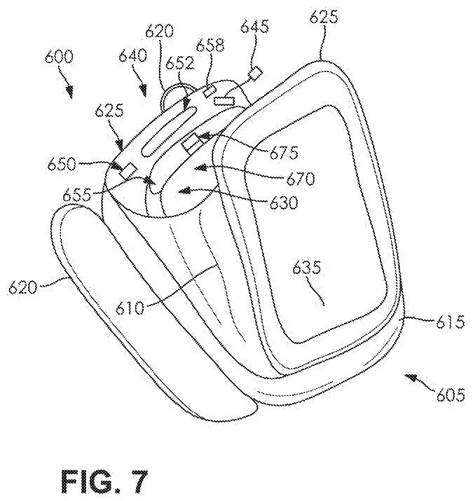

FIG. 7 illustrates system 600, an exemplary embodiment of a device that may be electrically connected to system 100 as described above. System 600 may include a structural assembly 605. Structural assembly 605 may include a plurality of members 610 (e.g., disposed in and/or outside of system 600) and sheet members 615 that may be configured (e.g., attached together) to form any desired piece of equipment such as, for example, a backpack, a piece of luggage, a carrying case, or any other desired equipment. Member 610 may be formed from similar material as member 115, and sheet member 615 may be formed from similar material as sheet member 110. In at least some exemplary embodiments, system 600 may be a backpack that may be used with system 100 or any other suitable system (e.g., a camping system or a beach system). System 600 may include any suitable components for transporting material (e.g., for a backpack) such as one or more members 620 (e.g., straps), and/or one or more members 625 for selectively opening and closing compartments (e.g., zippers or buttons). Members 625 may be selectively opened or closed to allow access to one or more cavities 630 (e.g., cargo areas). Structural assembly 605 may for example form a backpack including one or more flexible side portions 635.

System 600 may also include a power source 635 that may be similar to power source 125. In at least some exemplary embodiments, power source 635 may be a solar panel for example as described herein. Power source 635 may be disposed at a top portion of structural assembly 605 such as, for example, at one or more sheet members 615 and members 610 forming a top of structural assembly 605 for example as illustrated in FIG. 7. Power source 635 may be electrically connected to a connector assembly 640 that may be similar to connector assembly 165. For example, connector assembly 640 may include one or more electrical connectors 645 and 650 that may be similar to electrical connectors 170, 175, and 178. In at least some exemplary embodiments, electrical connector 645 may be a USB charging connector or any other desired electrical connector for example as described herein. In at least some exemplary embodiments, electrical connector 650 may be an electrical cable that may be connected to electrical component 150. Electrical connector 650 may be for example an extendable and retractable electrical connector that may be selectively extended and retracted from and into system 600. For example, electrical connector 650 may electrically connect power source 635 and electrical component 150. Also, power source 635 may provide electrical power to other devices via electrical connector 645. Further, electrical component 150 may provide electrical power to the devices removably attached to electrical connector 645 and/or electrical connector 650. System 600 may also include an electrical component 652 that may be electrically connected to connector assembly 640 and that may be similar to electrical component 150. Electrical component 652 may for example include a power storage such as a battery (e.g., a 6V battery or battery of any other suitable voltage level) and/or a controller. Electrical component 150 and/or the electrical component of system 600 may control electrical flow and/or charging (e.g., power flow) to and from the exemplary disclosed devices of system 100.

System 600 may include a thermal device 655 that may include a thermal assembly that may be similar to thermal assembly 500. In at least some exemplary embodiments, thermal device 655 may be a solid state heating and cooling liquid container. Thermal device 655 may include a housing 670 for storing a liquid (e.g., water or other suitable beverage) and a thermal assembly similar to thermal assembly 500 for heating and/or cooling contents of the housing of thermal device 655 (e.g., via the exemplary disclosed Seebeck effect). Housing 670 may for example be selectively opened and closed via a cap 675. Thermal device 655 may include an electrical switch 658 that may be similar to electrical switch 204. Electrical switch 658 may be for example disposed at a surface of structural assembly 605 that may be accessible to a user of system 600, for example being attached to sheet member 615 and/or member 610. Electrical switch 658 may reverse a polarity of a circuit of a thermal component of thermal device 655 for example as described herein regarding FIG. 6. Electrical switch 658 may thereby selectively control whether thermal device 655 operates to provide heating or cooling and/or turns on and off.

FIG. 8 illustrates an exemplary network electrical circuit of the exemplary disclosed system, apparatus, and method. FIG. 8 illustrates an exemplary electrical configuration including system 100 (e.g., or system 300), system 215, and system 600. In at least some exemplary embodiments, the exemplary disclosed system may be a beach solar network including umbrella solar panels and a controller and batteries with interconnections to beach chairs with warming and/or cooling thermal drink holders (e.g., having a control system, solar panels, and batteries), a thermal food warmer and/or cooler, and an external charging cable and USB connection for electronic devices. System 100 (e.g., or system 300), one or more thermal devices 200, one or more systems 215, and/or one or more systems 600 may be electrically connected and may operate for example as illustrated in FIG. 8.

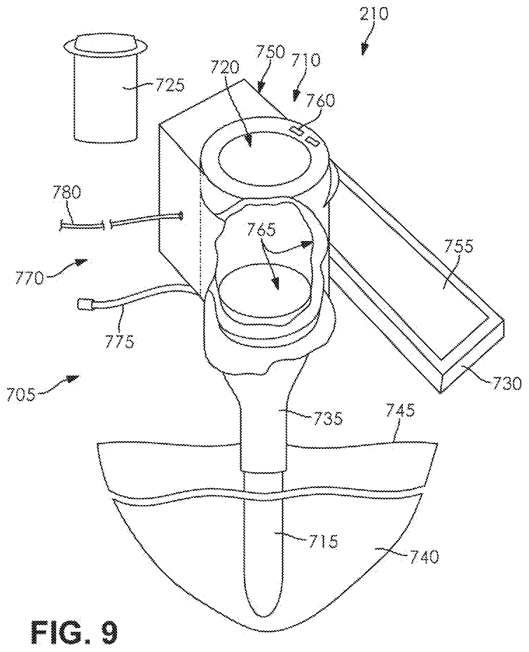

FIG. 9 illustrates an exemplary embodiment of thermal device 210. Thermal device 210 may include a structural assembly 705. Structural assembly 705 may include a receptacle portion 710 and a support member 715. Receptacle portion 710 may include a cavity 720 configured to receive a container 725 that may be similar to container 416. Structural assembly 705 may be formed from any suitable structural materials such as, for example, metal, plastic, composite material, or any other suitable structural material. A support member 730 may be attached to receptacle portion 710. Receptacle portion 710, support member 715, and support member 730 may be attached to each other via any suitable technique (e.g., snap-fit, via fasteners such as screws, bolts, and other mechanical fasteners, and/or via adhesive) and/or may be integrally formed with each other. For example, support member 730 may be removably attached to receptacle portion 710 (e.g., via a rotatable connection such as a snap-off hinge).

Support member 715 may be an elongated shape such as a spike. Support member 715 may be fixedly received or removably received in a receiving portion 735 of receptacle portion 710. Receiving portion 735 may be integrally formed with receptacle portion 710 or may be removably attachable to receptacle portion 710. For example, receiving portion 735 may include a fastener component (e.g., threaded end portion) that may be removably received in a corresponding portion of receptacle portion 710. For example, receiving portion 735 may be removably received (e.g., screwed into, bolted, or fastened by any other suitable technique) to receptacle portion 710. Receiving portion 735 and receptacle portion 710 may be formed partially or substantially entirely from thermally insulating material such as plastic or other suitable material. Receiving portion 735 may include a cavity for removably or fixedly receiving support member 715. Support member 715 may extend through a cavity of receiving portion 735 and may be in contact (e.g., thermal contact) with walls forming cavity 720. Support member 715 may thereby provide thermal transfer from cavity 720 (e.g., container 725 disposed in cavity 720) to a ground material in which support member 715 may be disposed. For example, support member 715 may be a spike or other pointed elongated member that may be driven by a user into a ground surface material such as dirt, sand (e.g., beach sand), grass, or any other suitable ground material into which support member 715 may be driven. Thermal device 210 may be removably inserted into a ground surface via support member 715. In at least some exemplary embodiments, support member 715 may be a thermal-conducting spike. Support member 715 may be driven into a relatively cooler ground material 740 disposed below a top surface 745 of the ground (e.g., cooler and/or wetter sand or dirt disposed a few inches below a top of a ground surface). By thermally connecting surfaces of cavity 720 with this relatively cooler ground material 740 disposed under top surface 745, support member 715 may facilitate heat transfer to and from thermal device 210. Support member 715 may also provide a stabilizing mechanism for supporting and substantially fixing thermal device 210 in the ground. In at least some exemplary embodiments, support member 715 may be a removable thermal spike (e.g., removable and replaceable in receiving portion 735) that may facilitate the removal of heat or cold away from thermal device 210 by inserting it into the sand or ground. In at least some exemplary embodiments, support member 715 may be removed so that thermal device 210 may be placed on any suitable flat surface. In at least some exemplary embodiments, removable attachable support member 715 may be removed so that thermal device 215 may be placed in a cup holder such as a side pocket of chair (e.g., to serve similarly as thermal device 415).

Thermal device 210 may include an electrical component 750 (e.g., having a power storage and a controller) that may be similar to electrical component 150. Electrical component 750 may for example be attached to receptacle portion 710. For example, electrical component 750 may be disposed in a housing that may be formed from similar material as receptacle portion 710 and that may be attached to or integrally formed with receptacle portion 710.

Thermal device 210 may also include a power source 755 that may be similar to power source 125 and that may be attached to an upper surface of support member 730 by any suitable technique such as via fasteners, adhesive, snap-fit, or any other suitable technique. Power source 755 may be electrically connected to electrical component 750 via one or more electrical connectors that may be disposed on or in receptacle portion 710 and that may be similar to electrical connector 135. Support member 730 and power source 755 may together provide a movable and/or detachable solar panel.

Thermal device 210 may further include an electrical switch 760 and a thermal component 765. Electrical switch 760 may be similar to electrical switch 204 and may be disposed on a surface of receptacle portion 710 (e.g., on a lip of a wall member forming cavity 720). Electrical switch 760 may reverse a polarity of a circuit of thermal component 765 for example as described herein regarding FIG. 6. Electrical switch 760 may thereby selectively control whether thermal component 765 operates to heat or cool and/or turns on and off.

Thermal component 765 may include components similar to as described herein regarding FIG. 6. Thermal component 765 may be attached to or integrally formed with receptacle portion 710. Thermal component 765 including components similar to as described herein regarding FIG. 6 may form side walls and a bottom wall that form cavity 720. Thermal component 765 may be electrically connected to electrical component 750 (e.g., and/or power source 755) and electrical switch 760 via one or more electrical connectors that may be disposed on or in receptacle portion 710 and that may be similar to electrical connector 135. Thermal component 765 may thereby operate to cool or heat surfaces of cavity 720 to cool or heat contents of container 725 based on being powered by electrical component 750 and/or power source 755. An operation of thermal component 765 may be similar to as described herein regarding FIG. 6.

Thermal device 210 may also include a connector assembly 770 that may be similar to connector assembly 165. For example, connector assembly 770 may include one or more electrical connectors 775 and 780 that may be similar to electrical connectors 170, 175, and 178. In at least some exemplary embodiments, electrical connector 775 may be an electrical connector of any desired voltage level (e.g., a 12V connector), a USB charging connector, or any other desired electrical connector for example as described herein. In at least some exemplary embodiments, electrical connector 780 may be an electrical cable that may be connected to electrical component 150. For example, electrical connector 780 may electrically connect electrical component 750 and electrical component 150 so that electrical components 750 and/or 150 may control electrical flow and/or charging (e.g., power flow) to and from the exemplary disclosed devices of system 100.

In at least some exemplary embodiments, thermal device 210 may be a thermal drink holder including a solar panel and batteries to provide power for warming and cooling a beverage. Thermal device 210 may include a spike for supporting (e.g., sticking) thermal device 210 into the sand.

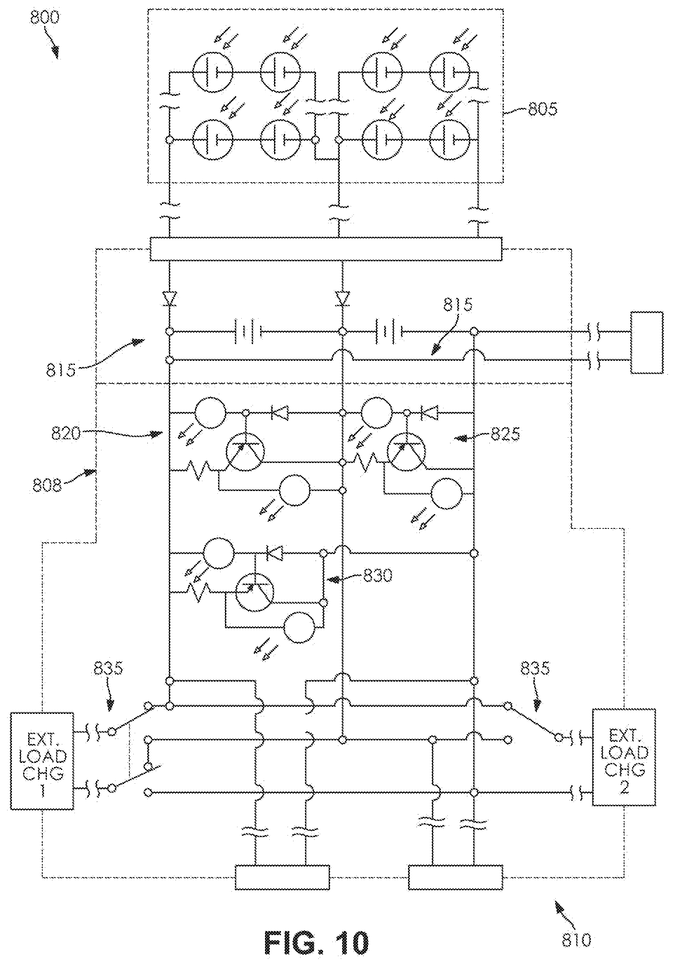

FIG. 10 illustrates a control circuit 800 for controlling an operation of any of the exemplary disclosed embodiments. Control circuit 800 may be integrated into any of the exemplary disclosed systems described herein. For example, electrical components 150, 350, 390, and the other exemplary disclosed electrical components may control an operation of control circuit 800. Control circuit 800 may provide for improved control and may include high and low LEDs (e.g., LEDs indicating high and low charge) for example disposed on the exemplary disclosed electrical components (e.g., electrical components 150, 350, 390, and the other exemplary disclosed electrical components) to display a state of charge of the exemplary disclosed energy storages (e.g., batteries, for example of electrical components 150, 350, 390, and the other exemplary disclosed electrical components). In at least some exemplary embodiments, control circuit 800 may include 6V batteries and 12V batteries. Control circuit 800 may also include switches (e.g., mechanical, electrical, or electromechanical switches) to transfer between the battery sources (e.g., 6V batteries) for external devices (e.g., 6V devices such as the beach chairs). Any suitable circuit configuration may be used to automatically switch loads between sources (e.g., electrical components including power storage) when one source may be running lower than another source.

As illustrated in FIG. 10, control circuit 800 may include a power source assembly 805 that may be similar to power source assembly 120 and a connector assembly 810 (e.g., including external 12V charging cables or charging cable of any other voltage level, USB connectors) that may be similar to connector assembly 165. Power source assembly 805 may be electrically connected to a control and sensor section 808 that may include similar components to electrical component 150.

Control circuit 800 may also include a plurality of power storages such as batteries 815 (e.g., primary batteries such as 6V batteries) that may be similar to power storages of electrical components 150, 350, 390, and the other exemplary disclosed electrical components. For example, batteries 815 may form “power packs” connected to power source assembly 805 (e.g., a set of solar panels). Control circuit 800 may also include an assembly 820 (e.g., a first source or source A, for example a 6V source), an assembly 825 (e.g., a second source or source B, for example a 6V source), and an assembly 830 (e.g., a third source or source A+B, for example a 12V source) as illustrated in FIG. 10. Control circuit 800 may also include a plurality of electrical switches 835 that may be similar to electrical switch 204 and that may switch loads between sources as illustrated in FIG. 10. Control circuit 800 may provide switching between batteries 815 (e.g., power packs) to switch an output load from a first battery 815 to a second battery 815 when the first battery 815 has a lower voltage than the second battery 815. Control circuit 800 may be integrated into any of the exemplary disclosed systems so that a plurality of cables and/or connectors (e.g., as illustrated in FIGS. 8, 10, and 13) may interconnect a plurality of pieces of equipment (e.g., beach or camping equipment) and may be powered by electricity transferred from the exemplary disclosed power sources (e.g., solar panels). For example, power storages such as batteries 815 may receive power from the exemplary disclosed power sources (e.g., power sources 125, 205, 385, 635, 755, 925, and/or 1010).

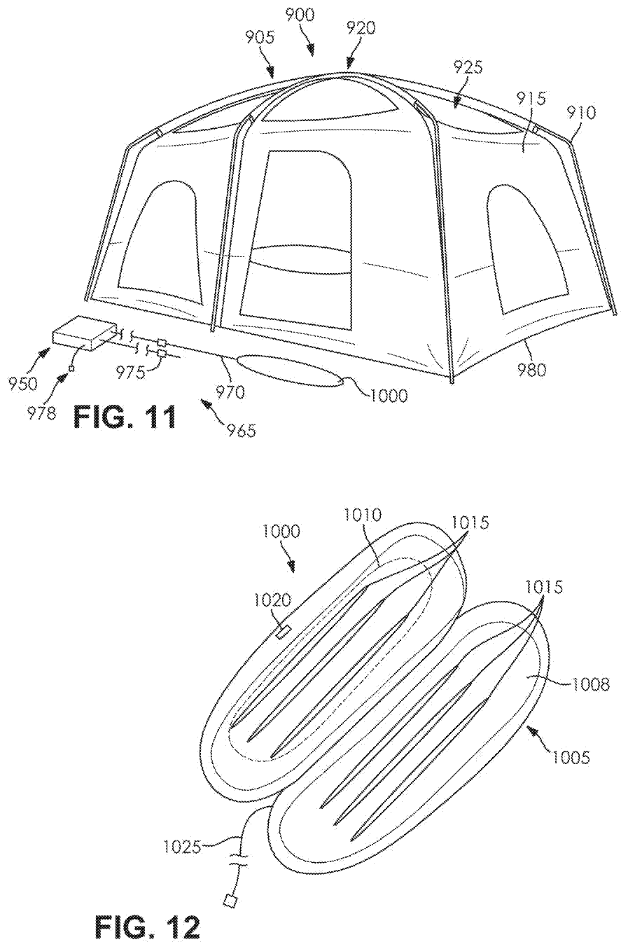

FIG. 11 illustrates another exemplary embodiment of the exemplary disclosed system, apparatus, and method. System 900 may include a structural assembly 905 having one or more members 910 that may be similar to members 370 and one or more sheet members 915 that may be similar to sheet members 375. Structural assembly 905 may be a collapsible structure that may be erected and dismantled such as, for example, a tent (e.g., a tent for camping) or any other suitable structure.

System 900 may include a power source assembly 920 including a plurality of power sources 925 that may be attached to structural assembly 905, similar to power source assembly 120 including the plurality of power sources 125 attached to structural assembly 105. In at least some exemplary embodiments, power sources 125 may be thin film solar panels that may be attached to an upper portion (e.g., a canopy or ceiling) of structural assembly 905 that may be a tent.

System 900 may also include an electrical component 950 (e.g., including one or more power storages such as a battery and a controller) that may be electrically connected to power source assembly 920. System 900 may also include a connector assembly 965 that may be similar to connector assembly 165. For example, connector assembly 965 may include one or more electrical connectors 970, 975, and 978 that may be similar to electrical connectors 170, 175, and 178. Electrical connectors 970, 975, and 978 may be provided inside and/or outside of structural assembly 905. In at least some exemplary embodiments, electrical connectors 970 and 975 may be a charging cable, a USB charging connector, or any other desired electrical connector for example as described herein. For example, electrical connector 970 may electrically connect electrical component 950 with a system 1000 (e.g., described below regarding FIG. 12) or any other suitable system (for example any of the exemplary disclosed systems described herein). In at least some exemplary embodiments, electrical connector 978 may be an electrical cable that may be connected to any other exemplary electrical component described herein. For example, electrical connector 978 may electrically connect electrical component 950 and any other exemplary electrical component described herein so that electrical components 950 and/or the other electrical component may control electrical flow and/or charging (e.g., power flow) to and from the exemplary disclosed devices of system 900. Any suitable systems and devices of system 100 may be included in system 900 (e.g., electrically connected to electrical component 950). In at least some exemplary embodiments, system 900 may be electrically connected to system 100 to form a combined electrical system (e.g., including some or all of the exemplary disclosed systems and devices described herein). System 900 may also include a thermal component 980 that may form a floor of structural assembly 905. Thermal component 980 may be similar to thermal component 202 and may operate to heat and/or cool a floor of structural assembly 905. For example as described herein regarding FIG. 6, a cooling side of thermal component 980 may face a ground surface, which may facilitate thermal conduction from structural assembly 905. In at least some exemplary embodiments, system 900 may be a camping solar network system including a tent with thin film solar panels and batteries with cables for external charging and USB connectors.

As illustrated in FIG. 12, system 1000 may include an assembly 1005. Assembly 1005 may be a sleeping assembly such as a sleeping bag. Assembly 1005 may be selectively opened (e.g., via a zipper or other suitable fastener) to expose interior surfaces 1008 and to access an inside of assembly 1005 for example as illustrated in FIG. 12. Assembly 1005 may be formed from any suitable material for forming a sleeping assembly such as material similar to sheet member 110, textiles, fabric, and any other suitable materials for thermally insulating a user such as a person sleeping in assembly 1005. A plurality of power sources 1010 that may be similar to power sources 125 may be attached (e.g., fastened, clipped, via adhesive, sewn, or attached via any other desired technique) to an exterior surface of assembly 1005. In at least some exemplary embodiments, power sources 1010 may be thin film solar panels. In at least some exemplary embodiments, system 1000 may be a solar sleeping bag (e.g., a winter solar sleeping bag and/or a summer sleeping bag). One or more (e.g., a plurality) thermal components 1015 that may include components similar to components of thermal component 765 may be disposed in assembly 1005 (e.g., within material of fabric of assembly 1005) and/or on interior surfaces 1008. In at least some exemplary embodiments, thermal component 1015 may be thermal heat Seebeck effect heat (e.g., or cooling) strips. Thermal component 1015 may include Graphene components (e.g., or other suitable material enhancing thermal conductivity) for example as described herein regarding FIG. 6. System 1000 may also include an electrical switch 1020 that may be similar to electrical switch 204 and that may be disposed at an exterior surface of assembly 1005 or at interior surface 1008. System 1000 may also include an electrical connector 1025 that may be similar to electrical connectors 170, 175, and/or 178. In at least some exemplary embodiments, electrical connector 1025 may be a 12V connector (e.g., or of any other suitable voltage) and may be electrically connected to one of the exemplary disclosed electrical components (e.g., electrical component 950, 150, or any other suitable component) or any other desired electrical component (e.g., a vehicle). Electrical connector 1025 may electrically connect power source 1010, thermal components 1015, and electrical switch 1020 so that thermal components 1015 may be powered (e.g., via power sources 1010 and/or external electrical components via electrical connector 1025) and controlled via electrical switch 1020 (e.g., to de-activate thermal components 1015 during warm weather and/or to cause thermal components 1015 to provide cooling of system 1000 during summer). For example, thermal components 1015 may be operated to provide heating or cooling depending on any suitable conditions such as ambient weather conditions. Assembly 1005 may also for example include a screen for a user to breathe through and/or look out of while inside assembly 1005.

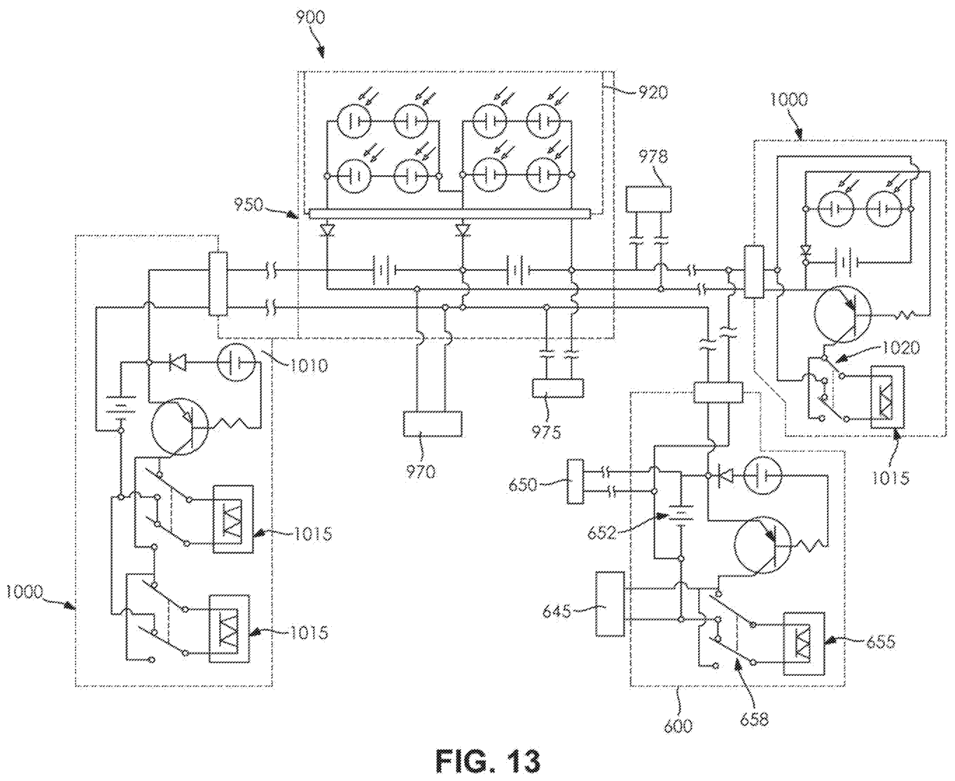

FIG. 13 illustrates an exemplary network electrical circuit of the exemplary disclosed system, apparatus, and method. FIG. 13 illustrates an exemplary electrical configuration including system 900, a plurality of systems 1000, and system 600. In at least some exemplary embodiments, the exemplary disclosed system may be a camping solar network including tent solar panels and a controller and batteries with interconnections to sleeping bags with warming and/or cooling components, a backpack, and external charging cables (e.g., to an exemplary disclosed thermal beverage holder and/or a food and beverage heater and cooler) and USB connections for electronic devices. System 900, the plurality of systems 1000, and system 600 may be electrically and operably connected for example as illustrated in FIG. 13.

In at least some exemplary embodiments, the exemplary control circuits may be used and electrical power may be increased by using a relatively large piece of equipment (e.g., an umbrella and/or a tent) that may incorporate large areas of solar panels to collect a significant amount of electrical energy. For example in the case of beach equipment such as in system 100, a large beach umbrella may be used. For example in the case of camping equipment, a tent may be used. Power packs (e.g., the exemplary disclosed electrical components) may be connected to the control network. Additionally, the use of suitably efficient solar panels for example as described herein (e.g., relatively lighter weight) and/or Graphene material may be used.

In at least some exemplary embodiments, thermal device 210 (e.g., the exemplary disclosed drink holder) may include a thermal drink holder. The exemplary disclosed thermal drink holder may incorporate a Seebeck Effect solid state heating or cooling surface to cool or warm drinks.

In at least some exemplary embodiments, the exemplary disclosed system, apparatus, and method may integrate the use of a beach umbrella that has a relatively large solar panel area on its top with beach chairs having drink holders (e.g., with a switch for changing between cooling and heating disposed in the arms of the chairs, and also having thin film solar panels on the sun shades) and also with a solar-powered food container (e.g., a “thermal cooler”) that has a switch to change between cooling and heating.

In at least some exemplary embodiments, the exemplary disclosed system, apparatus, and method may integrate the use of a relatively large solar panel area of a camping tent with the use of solar heated or cooled sleeping bags and backpacks and may also operate with Beach system items such as the exemplary disclosed drink holder or chair.

In at least some exemplary embodiments, the exemplary disclosed system, apparatus, and method may include a solar-paneled warm and/or cool drink holder with a metallic spike disposed at the bottom of the drink holder. The metallic spike may be pushed into the sand at a beach or the ground to act as a heat sink (e.g., being disposed in relatively cooler sand or ground below a surface to assist in transferring heat away from a heat side of the exemplary disclosed Seebeck effect solid state heating and/or cooling material).

In at least some exemplary embodiments, the exemplary disclosed system, apparatus, and method may include USB connectors and one or more external 12 Volt charging cables to allow for charging a plurality of energy storages (e.g., two 6 volt power packs in series) to provide a primary 12 Volts for energy storage and to allow a variety of products to be connected to the exemplary disclosed system (e.g., network).

In at least some exemplary embodiments, the exemplary disclosed system, apparatus, and method may integrate (e.g., electrically connect) a plurality of solar-powered items, which may each include thin film solar panels and batteries, with a main control component and battery packs that may be included on a relatively larger solar power source of a large beach umbrella. The exemplary disclosed thin film solar panels of the umbrella may be permanently attached to the umbrella or added to an umbrella having wind vent openings that allow solar panel cables to pass through, with the panels and/or cables being affixed with elastic bands that fit over the ends of the umbrella ribs. The thin film panels may be slightly weighted on their edges to assist in holding the panels to the surface of the umbrella and/or may be attached via any other suitable techniques. The exemplary disclosed panels may be folded with the umbrella.

In at least some exemplary embodiments, the exemplary disclosed system, apparatus, and method may include solar panels formed from materials having suitable conductivity, flexibility, and/or strength. For example, the exemplary disclosed system, apparatus, and method may include solar panels formed from Graphene material.

In at least some exemplary embodiments, the exemplary disclosed system, apparatus, and method may include thermal coolers and heaters such as drink holders disposed in arms of a chair in which a switch to reverse a current may reverse heating and cooling sides of a thermal unit (e.g., as described regarding FIG. 6), which may operate with a folding chair having a solar panel sun shade that may power primary batteries when the drink holder and/or USB devices are not in use (e.g., thereby providing added power to the system). Also for example, the exemplary disclosed system, apparatus, and method may include individual devices that may feed electrical power to charge the exemplary disclosed batteries for collective use by devices of the systems when a given device's own solar generator panels are producing more electricity than that given device utilizes.

In at least some exemplary embodiments, the exemplary disclosed apparatus may include a structural assembly having a cavity configured to removably receive a container, a renewable power source supported by the structural assembly, an electrical component (e.g., electrical component 150, 206, 350, 390, 652, 750, or 950) including a power storage supported by the structural assembly, a thermal assembly disposed at the cavity and configured to heat or cool the container when the container is received in the cavity, and an elongated support member attached to the structural assembly and configured to be inserted into the ground. The elongated support member may be removably attachable to the structural assembly. The elongated support member may be a metal spike. The renewable power source may be a solar panel that is removably attachable to the structural assembly. The solar panel may include a hinge that is removably attachable to the structural assembly. The thermal assembly may include a wall portion forming at least a portion of the cavity. The thermal assembly may include a N (−) negative doped semiconductor and a P (+) positive doped semiconductor that are disposed between a plurality of thermal conductors. The plurality of thermal conductors may be formed from Graphene material. The exemplary disclosed apparatus may also include an electrical switch that may be electrically connected to the thermal assembly. The electrical switch may reverse heating and cooling sides of thermal assembly based on reversing a polarity of the thermal assembly. The exemplary disclosed apparatus may further include an electrical switch. The electrical component may include a controller. The electrical switch, the electrical component, the thermal assembly, and the renewable power source may be electrically connected. The exemplary disclosed apparatus may also include at least one electrical connector electrically connected to the electrical component and selected from the group of a 12V connector and a USB charging connector.

In at least some exemplary embodiments, the exemplary disclosed method may include a structural assembly having a cavity configured to removably receive a container, supporting a renewable power source with the structural assembly, supporting an electrical component (e.g., electrical component 150, 206, 350, 390, 652, 750, or 950) including a power storage and a controller with the structural assembly, heating or cooling the container when the container is received in the cavity using a thermal assembly disposed at the cavity, removably attaching an elongated support member to the structural assembly, and supporting the structural assembly on the ground by inserting the elongated support member into the ground. The exemplary disclosed method may also include providing an electrical switch, electrically connecting the electrical component, the thermal assembly, the renewable power source, and the electrical switch, and reversing a polarity of the thermal assembly to switch between heating and cooling the container based on controlling the electrical switch with the controller. The thermal assembly may include a N (−) negative doped semiconductor and a P (+) positive doped semiconductor that are disposed between a plurality of thermal conductors. The exemplary disclosed method may further include removing thermal energy from the thermal assembly to the ground via the elongated support member. The elongated support member may be a metal spike. The exemplary disclosed method may further include removing the elongated support member from the structural assembly, and disposing a substantially flat bottom portion of the structural assembly on a surface when the elongated support member is removed. The exemplary disclosed method may also include electrically connecting the electrical component to an electrical device selected from the group of an umbrella including a solar panel, a chair including a solar panel, a backpack including a solar panel, a cooler including a solar panel, a tent including a solar panel, and a sleeping bag including a solar panel.

In at least some exemplary embodiments, the exemplary disclosed apparatus may include a structural assembly having a cavity configured to removably receive the container, a solar panel removably attachable to the structural assembly, an electrical component (e.g., electrical component 150, 206, 350, 390, 652, 750, or 950) including a power storage and a controller supported by the structural assembly, a thermal assembly disposed at the cavity and configured to heat or cool the container when the container is received in the cavity, and a metal spike removably attachable to the structural assembly. The exemplary disclosed apparatus may also include an electrical switch. The electrical switch, the electrical component, the thermal assembly, and the solar panel may be electrically connected. The solar panel may charge the power storage of the electrical component. The power storage of the electrical component may power the controller of the electrical component, the thermal assembly, and the electrical switch. The thermal assembly may include a wall portion forming at least a portion of the cavity, the wall portion including a N (−) negative doped semiconductor and a P (+) positive doped semiconductor that may be disposed between a plurality of Graphene sheets.

The exemplary disclosed system, apparatus, and method may be used in any suitable application for providing a power source. For example, the exemplary disclosed system, apparatus, and method may be used for providing a power source for equipment such as outdoor equipment. The exemplary disclosed system, apparatus, and method may be used to provide a power source for recreational equipment such as beach equipment and camping equipment.

For example as illustrated in FIGS. 3 and 8, an exemplary operation of the exemplary disclosed system, apparatus, and method (e.g., system 100) will be described. Any of the exemplary disclosed controllers (e.g., controller of electrical component 150) may operate to control system 100. User device 180 may be used by a user to control electrical component 150 (e.g., via transferring input commands) and/or electrical component 150 may operate based on predetermined algorithms or any other suitable control technique. Power sources 125 may operate to collect solar energy and transfer electricity to charge the exemplary disclosed power storage of electrical component 150. Also for example, power source 205 may charge electrical component 206 of thermal device 200. Systems 215, 600, and thermal device 210 may generate and transfer electricity. Any of the exemplary disclosed electrical components may operate to control a flow of electricity between devices, power sources, and electrical components. For example, electrical component 150 may operate to control the other exemplary disclosed devices to transfer electricity to electrical component 150 to charge power storages of electrical component 150, to charge any other of the exemplary disclosed electrical components (e.g., electrical components 206, 350, 390, 652, 750, and/or 950), and/or to directly power any of the exemplary disclosed devices. Electrical component 150 may thereby operate to transfer electricity from the exemplary disclosed power sources and to charge or power any of the exemplary disclosed devices and power storages for example as illustrated in FIG. 8 (e.g., and/or FIGS. 10 and 13). The exemplary disclosed electrical switches (e.g., electrical switches 204, 418, 658, 760, 835, and/or 1020) may be operated by a user to switch thermal devices between on and off, and between heating and cooling, as they are powered via the exemplary disclosed power sources based on control by the exemplary disclosed controller (e.g., controllers of electrical components 206, 350, 390, 652, 750, and/or 950).

The exemplary disclosed system, apparatus, and method may provide an efficient and effective technique for providing a power source to equipment. For example, the exemplary disclosed system, apparatus, and method may add network interconnectivity for providing power to multiple pieces of equipment. The exemplary disclosed system, apparatus, and method may also provide for devices and parts to be connected and powered by equipment that is powered by the exemplary disclosed system, apparatus, and method. The exemplary disclosed system, apparatus, and method may further increase available electrical power to equipment.

In the Summary above and in this Detailed Description, and the claims below, and in the accompanying drawings, reference is made to particular features of various embodiments of the invention. It is to be understood that the disclosure of embodiments of the invention in this specification includes all possible combinations of such particular features. For example, where a particular feature is disclosed in the context of a particular aspect or embodiment of the invention, or a particular claim, that feature can also be used—to the extent possible—in combination with and/or in the context of other particular aspects and embodiments of the invention, and in the invention generally.

While multiple embodiments are disclosed, still other embodiments of the present invention will become apparent to those skilled in the art from this detailed description. The invention is capable of myriad modifications in various obvious aspects, all without departing from the spirit and scope of the present invention. Accordingly, the drawings and descriptions are to be regarded as illustrative in nature and not restrictive.

It should be noted that the features illustrated in the drawings are not necessarily drawn to scale, and features of one embodiment may be employed with other embodiments as the skilled artisan would recognize, even if not explicitly stated herein. Descriptions of well-known components and processing techniques may be omitted so as to not unnecessarily obscure the embodiments.

In the present disclosure, various features may be described as being optional, for example, through the use of the verb “may;”, or, through the use of any of the phrases: “in some embodiments,” “in some implementations,” “in some designs,” “in various embodiments,” “in various implementations,”, “in various designs,” “in an illustrative example,” or “for example;” or, through the use of parentheses. For the sake of brevity and legibility, the present disclosure does not explicitly recite each and every permutation that may be obtained by choosing from the set of optional features. However, the present disclosure is to be interpreted as explicitly disclosing all such permutations. For example, a system described as having three optional features may be embodied in seven different ways, namely with just one of the three possible features, with any two of the three possible features or with all three of the three possible features.

In various embodiments. elements described herein as coupled or connected may have an effectual relationship realizable by a direct connection or indirectly with one or more other intervening elements.

In the present disclosure, the term “any” may be understood as designating any number of the respective elements, i.e. as designating one, at least one, at least two, each or all of the respective elements. Similarly, the term “any” may be understood as designating any collection(s) of the respective elements, i.e. as designating one or more collections of the respective elements, a collection comprising one, at least one, at least two, each or all of the respective elements. The respective collections need not comprise the same number of elements.

While various embodiments of the present invention have been disclosed and described in detail herein, it will be apparent to those skilled in the art that various changes may be made to the configuration, operation and form of the invention without departing from the spirit and scope thereof. In particular, it is noted that the respective features of embodiments of the invention, even those disclosed solely in combination with other features of embodiments of the invention, may be combined in any configuration excepting those readily apparent to the person skilled in the art as nonsensical. Likewise, use of the singular and plural is solely for the sake of illustration and is not to be interpreted as limiting.

In the present disclosure, all embodiments where “comprising” is used may have as alternatives “consisting essentially of,” or “consisting of.” In the present disclosure, any method or apparatus embodiment may be devoid of one or more process steps or components. In the present disclosure, embodiments employing negative limitations are expressly disclosed and considered a part of this disclosure.

Certain terminology and derivations thereof may be used in the present disclosure for convenience in reference only and will not be limiting. For example, words such as “upward,” “downward,” “left,” and “right” would refer to directions in the drawings to which reference is made unless otherwise stated. Similarly, words such as “inward” and “outward” would refer to directions toward and away from, respectively, the geometric center of a device or area and designated parts thereof. References in the singular tense include the plural, and vice versa, unless otherwise noted.

The term “comprises” and grammatical equivalents thereof are used herein to mean that other components, ingredients, steps, among others, are optionally present. For example, an embodiment “comprising” (or “which comprises”) components A, B and C can consist of (i.e., contain only) components A, B and C, or can contain not only components A, B, and C but also contain one or more other components.

Where reference is made herein to a method comprising two or more defined steps, the defined steps can be carried out in any order or simultaneously (except where the context excludes that possibility), and the method can include one or more other steps which are carried out before any of the defined steps, between two of the defined steps, or after all the defined steps (except where the context excludes that possibility).

Many suitable methods and corresponding materials to make each of the individual parts of embodiment apparatus are known in the art. According to an embodiment of the present invention, one or more of the parts may be formed by machining, 3D printing (also known as “additive” manufacturing), CNC machined parts (also known as “subtractive” manufacturing), and injection molding, as will be apparent to a person of ordinary skill in the art. Metals, wood, thermoplastic and thermosetting polymers, resins and elastomers as may be described herein-above may be used. Many suitable materials are known and available and can be selected and mixed depending on desired strength and flexibility, preferred manufacturing method and particular use, as will be apparent to a person of ordinary skill in the art.

Any element in a claim herein that does not explicitly state “means for” performing a specified function, or “step for” performing a specific function, is not to be interpreted as a “means” or “step” clause as specified in 35 U.S.C. § 112 (f). Specifically, any use of “step of” in the claims herein is not intended to invoke the provisions of 35 U.S.C. § 112 (f).

According to an embodiment of the present invention, the system and method may be accomplished through the use of one or more computing devices. One of ordinary skill in the art would appreciate that an exemplary system appropriate for use with embodiments in accordance with the present application may generally include one or more of a Central processing Unit (CPU), Random Access Memory (RAM), a storage medium (e.g., hard disk drive, solid state drive, flash memory, cloud storage), an operating system (OS), one or more application software, a display element, one or more communications means, or one or more input/output devices/means. Examples of computing devices usable with embodiments of the present invention include, but are not limited to, proprietary computing devices, personal computers, mobile computing devices, tablet PCs, mini-PCs, servers or any combination thereof. The term computing device may also describe two or more computing devices communicatively linked in a manner as to distribute and share one or more resources, such as clustered computing devices and server banks/farms. One of ordinary skill in the art would understand that any number of computing devices could be used, and embodiments of the present invention are contemplated for use with any computing device.

In various embodiments, communications means, data store(s), processor(s), or memory may interact with other components on the computing device, in order to effect the provisioning and display of various functionalities associated with the system and method detailed herein. One of ordinary skill in the art would appreciate that there are numerous configurations that could be utilized with embodiments of the present invention, and embodiments of the present invention are contemplated for use with any appropriate configuration.

According to an embodiment of the present invention, the communications means of the system may be, for instance, any means for communicating data over one or more networks or to one or more peripheral devices attached to the system. Appropriate communications means may include, but are not limited to, circuitry and control systems for providing wireless connections, wired connections, cellular connections, data port connections, Bluetooth connections, or any combination thereof. One of ordinary skill in the art would appreciate that there are numerous communications means that may be utilized with embodiments of the present invention, and embodiments of the present invention are contemplated for use with any communications means.

Throughout this disclosure and elsewhere, block diagrams and flowchart illustrations depict methods, apparatuses (i.e., systems), and computer program products. Each element of the block diagrams and flowchart illustrations, as well as each respective combination of elements in the block diagrams and flowchart illustrations, illustrates a function of the methods, apparatuses, and computer program products. Any and all such functions (“disclosed functions”) can be implemented by computer program instructions; by special-purpose, hardware-based computer systems; by combinations of special purpose hardware and computer instructions; by combinations of general purpose hardware and computer instructions; and so on—any and all of which may be generally referred to herein as a “circuit,” “module,” or “system.”

While the foregoing drawings and description may set forth functional aspects of the disclosed systems, no particular arrangement of software for implementing these functional aspects should be inferred from these descriptions unless explicitly stated or otherwise clear from the context.

Each element in flowchart illustrations may depict a step, or group of steps, of a computer-implemented method. Further, each step may contain one or more sub-steps. For the purpose of illustration, these steps (as well as any and all other steps identified and described above) are presented in order. It will be understood that an embodiment can contain an alternate order of the steps adapted to a particular application of a technique disclosed herein. All such variations and modifications are intended to fall within the scope of this disclosure. The depiction and description of steps in any particular order is not intended to exclude embodiments having the steps in a different order, unless required by a particular application, explicitly stated, or otherwise clear from the context.

Traditionally, a computer program consists of a sequence of computational instructions or program instructions. It will be appreciated that a programmable apparatus (i.e., computing device) can receive such a computer program and, by processing the computational instructions thereof, produce a further technical effect.

A programmable apparatus may include one or more microprocessors, microcontrollers, embedded microcontrollers, programmable digital signal processors, programmable devices, programmable gate arrays, programmable array logic, memory devices, application specific integrated circuits, or the like, which can be suitably employed or configured to process computer program instructions, execute computer logic, store computer data, and so on. Throughout this disclosure and elsewhere a computer can include any and all suitable combinations of at least one general purpose computer, special-purpose computer, programmable data processing apparatus, processor, processor architecture, and so on.

It will be understood that a computer can include a computer-readable storage medium and that this medium may be internal or external, removable and replaceable, or fixed. It will also be understood that a computer can include a Basic Input/Output System (BIOS), firmware, an operating system, a database, or the like that can include, interface with, or support the software and hardware described herein.

Embodiments of the system as described herein are not limited to applications involving conventional computer programs or programmable apparatuses that run them. It is contemplated, for example, that embodiments of the invention as claimed herein could include an optical computer, quantum computer, analog computer, or the like.

Regardless of the type of computer program or computer involved, a computer program can be loaded onto a computer to produce a particular machine that can perform any and all of the disclosed functions. This particular machine provides a means for carrying out any and all of the disclosed functions.

Any combination of one or more computer readable medium(s) may be utilized. The computer readable medium may be a computer readable signal medium or a computer readable storage medium. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer readable storage medium may be any tangible medium that can contain or store a program for use by or in connection with an instruction execution system, apparatus, or device.

In some embodiments, computer program instructions may be stored in a computer-readable memory capable of directing a computer or other programmable data processing apparatus to function in a particular manner. The instructions stored in the computer-readable memory constitute an article of manufacture including computer-readable instructions configured to implement any and all of the disclosed functions.

A computer readable signal medium may include a propagated data signal with computer readable program code embodied therein, for example, in baseband or as part of a carrier wave. Such a propagated signal may take any of a variety of forms, including, but not limited to, electromagnetic, optical, or any suitable combination thereof. A computer readable signal medium may be any computer readable medium that is not a computer readable storage medium and that can communicate, propagate, or transport a program for use by or in connection with an instruction execution system, apparatus, or device.

Program code embodied on a computer readable medium may be transmitted using any appropriate medium, including but not limited to wireless, wireline, optical fiber cable, RF, etc., or any suitable combination of the foregoing.

The elements depicted in flowchart illustrations and block diagrams throughout the figures imply logical boundaries between the elements. However, according to software or hardware engineering practices, the disclosed elements and the functions thereof may be implemented as parts of a monolithic software structure, as standalone software modules, or as modules that employ external routines, code, services, and so forth, or any combination of these. All such implementations are within the scope of the present disclosure.

Unless explicitly stated or otherwise clear from the context, the verbs “execute” and “process” are used interchangeably to indicate execute, process, interpret, compile, assemble, link, load, any and all combinations of the foregoing, or the like. Therefore, embodiments that execute or process computer program instructions, computer-executable code, or the like can suitably act upon the instructions or code in any and all of the ways just described.

The functions and operations presented herein are not inherently related to any particular computer or other apparatus. Various general-purpose systems may also be used with programs in accordance with the teachings herein, or it may prove convenient to construct more specialized apparatus to perform the required method steps. The required structure for a variety of these systems will be apparent to those of skill in the art, along with equivalent variations. In addition, embodiments of the invention are not described with reference to any particular programming language. It is appreciated that a variety of programming languages may be used to implement the present teachings as described herein, and any references to specific languages are provided for disclosure of enablement and best mode of embodiments of the invention. Embodiments of the invention are well suited to a wide variety of computer network systems over numerous topologies. Within this field, the configuration and management of large networks include storage devices and computers that are communicatively coupled to dissimilar computers and storage devices over a network, such as the Internet.

A number of implementations have been described. Nevertheless, it will be understood that various modifications may be made. For example, advantageous results may be achieved if the steps of the disclosed techniques were performed in a different sequence, or if components of the disclosed systems were combined in a different manner, or if the components were supplemented with other components. Accordingly, other implementations are contemplated within the scope of the following claims.

What is claimed is:

1. An apparatus for removably receiving a container, comprising:
a structural assembly having a cavity configured to removably receive the container;
a renewable power source supported by the structural assembly;
an electrical component including a power storage supported by the structural assembly;
a thermal assembly disposed at the cavity and configured to heat or cool the container when the container is received in the cavity; and
an elongated support member attached to the structural assembly and configured to be inserted into the ground.

2. The apparatus of claim 1, wherein the elongated support member is removably attachable to the structural assembly.

3. The apparatus of claim 1, wherein the elongated support member is a metal spike.

4. The apparatus of claim 1, wherein the renewable power source is a solar panel that is removably attachable to the structural assembly.

5. The apparatus of claim 4, wherein the solar panel includes a hinge that is removably attachable to the structural assembly.

6. The apparatus of claim 1, wherein the thermal assembly includes a wall portion forming at least a portion of the cavity.

7. The apparatus of claim 1, wherein the thermal assembly includes a N (−) negative doped semiconductor and a P (+) positive doped semiconductor that are disposed between a plurality of thermal conductors.

8. The apparatus of claim 7, wherein the plurality of thermal conductors are formed from Graphene material.

9. The apparatus of claim 7, further comprising an electrical switch that is electrically connected to the thermal assembly;
wherein the electrical switch reverses heating and cooling sides of the thermal assembly based on reversing a polarity of the thermal assembly.

10. The apparatus of claim 1, further comprising an electrical switch;
wherein the electrical component includes a controller; and
wherein the electrical switch, the electrical component, the thermal assembly, and the renewable power source are electrically connected.

11. The apparatus of claim 1, further comprising at least one electrical connector electrically connected to the electrical component and selected from the group of a 12V connector and a USB charging connector.

12. A method, comprising:
a structural assembly having a cavity configured to removably receive a container;
supporting a renewable power source with the structural assembly;
supporting an electrical component including a power storage and a controller with the structural assembly;
heating or cooling the container when the container is received in the cavity using a thermal assembly disposed at the cavity;
removably attaching an elongated support member to the structural assembly; and
supporting the structural assembly on the ground by inserting the elongated support member into the ground.

13. The method of claim 12, further comprising:
providing an electrical switch;
electrically connecting the electrical component, the thermal assembly, the renewable power source, and the electrical switch; and
reversing a polarity of the thermal assembly to switch between heating and cooling the container based on controlling the electrical switch with the controller.

14. The method of claim 13, wherein the thermal assembly includes a N (−) negative doped semiconductor and a P (+) positive doped semiconductor that are disposed between a plurality of thermal conductors.

15. The method of claim 12, further comprising removing thermal energy from the thermal assembly to the ground via the elongated support member;
wherein the elongated support member is a metal spike.

16. The method of claim 12, further comprising:
removing the elongated support member from the structural assembly; and
disposing a substantially flat bottom portion of the structural assembly on a surface when the elongated support member is removed.

17. The method of claim 12, further comprising electrically connecting the electrical component to an electrical device selected from the group of an umbrella including a solar panel, a chair including a solar panel, a backpack including a solar panel, a cooler including a solar panel, a tent including a solar panel, and a sleeping bag including a solar panel.

18. An apparatus for removably receiving a container, comprising:
a structural assembly having a cavity configured to removably receive the container;
a solar panel removably attachable to the structural assembly;
an electrical component including a power storage and a controller supported by the structural assembly;
a thermal assembly disposed at the cavity and configured to heat or cool the container when the container is received in the cavity; and
a metal spike removably attachable to the structural assembly.

19. The apparatus of claim 18, further comprising an electrical switch;
wherein the electrical switch, the electrical component, the thermal assembly, and the solar panel are electrically connected;
wherein the solar panel charges the power storage of the electrical component; and
wherein the power storage of the electrical component powers the controller of the electrical component, the thermal assembly, and the electrical switch.

20. The apparatus of claim 18, wherein the thermal assembly includes a wall portion forming at least a portion of the cavity, the wall portion including a N (−) negative doped semiconductor and a P (+) positive doped semiconductor that are disposed between a plurality of Graphene sheets.
